(19) United States
(12) Patent Application Publication
(10) Pub. No.: US 2019/0088829 A1
(43) Pub. Date: Mar. 21, 2019

(54) LIGHT SOURCE AND ILLUMINATION DEVICE

(71) Applicant: PANASONIC INTELLECTUAL PROPERTY MANAGEMENT CO., LTD., Osaka (JP)

(72) Inventors: Naoko TAKEI, Osaka (JP); Kenichiro TANAKA, Osaka (JP); Ikko KUZUHARA, Osaka (JP)

(73) Assignee: PANASONIC INTELLECTUAL PROPERTY MANAGEMENT CO., LT D., Osaka (JP)

(21) Appl. No.: 16/135,241

(22) Filed: Sep. 19, 2018

(30) Foreign Application Priority Data
Sep. 21, 2017 (JP) 2017-181835

(51) Int. Cl. H01L 33/50; H05B 33/08; H01L 33/44; G02B 27/09

(52) U.S. Cl. CPC H01L 33/502; G02B 27/0977; H01L 33/44; H05B 33/0857

(57) ABSTRACT

Provided is a light source that emits white light having a correlated color temperature of at least 2700 K and at most 7200 K, a chromaticity deviation within ±10, and an average color rendering index of at least 80. The light source includes: a solid-state light emitter that emits light of a first wavelength, and a fluorescent layer. The fluorescent layer receives light from the solid-state light emitter, and transmits light having a second wavelength after being excited by the light from the solid-state light emitter. The fluorescent layer includes: fluorescent materials of two or more types different in emission peak wavelength, a binder that includes a light-transmissive inorganic compound that fixes the fluorescent materials, and a void that is provided between the fluorescent materials.

### CROSS REFERENCE TO RELATED APPLICATION

This application claims the benefit of priority of Japanese Patent Application Number 2017-181835 filed on Sep. 21, 2017, the entire content of which is hereby incorporated by reference.

### BACKGROUND

### 1. Technical Field

The present disclosure relates to a light source and an illumination device that include a fluorescent material.

### 2. Description of the Related Art

There are conventionally known luminaries that include a solid-state light-emitting element such as a light-emitting diode (LED). Since LED illumination has low power consumption and long service life, the LED illumination has become popular in the field of general illumination for commercial use and household use, and is further becoming popular in the field of industrial illumination for outdoor use, manufacturing use, etc. With increasing use of the LED illumination, there has been a demand for making an LED light source compact and high-powered. For example, there is a demand for a compact and high-power LED light source because a light projector, an illumination installed to a high ceiling, a vehicle headlamp, etc. are required to emit light far.

An LED light source contains a light-emitting element that includes an LED chip, and a fluorescent material that performs wavelength conversion on light emitted by the light-emitting element, by absorbing part of the light. In the LED light source, white light is obtained by mixing light from the light-emitting element and light from the fluorescent material. In order to ensure high luminous efficacy, a yellow fluorescent material representing a YAG fluorescent material is often used as a fluorescent material for an LED light source that is required to be compact and high-powered. In addition, when a wavelength converter having a predetermined shape is made using the fluorescent material, ceramic processing or glass sealing is often used such that the wavelength converter does not become degenerated even under high temperature.

Particularly in the field of industrial illumination, there is a demand for high color rendering properties of white light from such an LED light source. A technique is proposed for including two or more types of fluorescent materials, such as a green fluorescent material and a red fluorescent material, in a wavelength converter so as to obtain white color with high color rendering properties (for example, Patent Literature (PTL) 1 (Japanese Unexamined Patent Application Publication No. 2006-351600)).

### SUMMARY

However, when the wavelength converter including the two or more types of the fluorescent materials having different properties is made in the same manner as the foregoing wavelength converter including only the yellow fluorescent material, the durability of the wavelength converter is likely to deteriorate. In other words, when high-power light is incident on the wavelength converter in which the fluorescent materials having the different properties are closely bound together, a problem may arise with the durability of the wavelength converter such as the occurrence of a crack resulting from a difference between coefficients of thermal expansion of the fluorescent materials.

In view of this, the present disclosure has an object to solve the above problem and provide a light source and an illumination device that are compact and high-powered, are highly durable, and can emit white light with high color rendering properties.

In order to achieve the above-described object, a light source according to one aspect of the present disclosure is a light source that emits white light. The white light has a correlated color temperature of at least 2700 K and at most 7200 K, a chromaticity deviation within 110, and an average color rendering index of at least 80. The light source includes: a solid-state light emitter that emits light having a first wavelength via a light-emitting face; a fluorescent layer that has a first face facing the solid-state light emitter and a second face positioned across from the first face, receives, via the first face, the light emitted by the solid-state light emitter, and transmits, via the second face, light having a second wavelength different from the first wavelength, the fluorescent layer being excited by the light received from the solid-state light emitter; and a light-transmissive adhesive that bonds the light-emitting face of the solid-state light emitter and the first face of the fluorescent layer. The fluorescent layer includes: a first fluorescent material of a first type having a first emission peak wavelength, and a second fluorescent material of a second type having a second emission peak wavelength; a binder that includes a light-transmissive inorganic compound that fixes the first fluorescent material and the second fluorescent material; and a void that is provided between the first fluorescent material and the second fluorescent material.

In order to achieve the above-described object, an illumination device according to one aspect of the present disclosure is an illumination device including the above-described light source.

According to one aspect of the present disclosure, it is possible to provide an illumination device that is compact and high-powered, is highly durable, and can emit white light with high color rendering properties.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a schematic plan view of a schematic configuration of a light source according to Embodiment 1;

FIG. 2 is a schematic cross-sectional diagram illustrating the schematic configuration of the light source according to Embodiment 1;

FIG. 3 is a schematic cross-sectional diagram illustrating a detailed configuration of a fluorescent layer according to Embodiment 1;

FIG. 4 is a schematic cross-sectional diagram illustrating a schematic configuration of a light source according to a variation of Embodiment 1;

FIG. 5 is a schematic cross-sectional diagram illustrating a schematic configuration of a light source according to Embodiment 2;

FIG. 6 is a schematic cross-sectional diagram illustrating a schematic configuration of a light source according to a variation of Embodiment 2;

FIG. 7 is a schematic cross-sectional diagram illustrating a schematic configuration of a light source according to Embodiment 3;

FIG. 8 is a schematic cross-sectional diagram illustrating a detailed configuration of a fluorescent layer according to Embodiment 3;

FIG. 9 is a schematic cross-sectional diagram illustrating a schematic configuration of a light source according to Embodiment 4;

FIG. 10 is a schematic cross-sectional diagram illustrating a detailed configuration of a fluorescent layer according to Embodiment 4;

FIG. 11 is a schematic cross-sectional diagram illustrating a schematic configuration of a light source according to a variation of Embodiment 4;

FIG. 12 is a schematic cross-sectional diagram illustrating a schematic configuration of a light source according to Embodiment 5; and

FIG. 13 is an external view of a vehicle including vehicle headlamps according to a variation.

### DETAILED DESCRIPTION OF THE EMBODIMENTS

Hereinafter, embodiments of the present disclosure will be described with reference to the drawings. Each of the embodiments described below shows a specific example of the present disclosure. Therefore, numerical values, shapes, materials, structural elements, the arrangement and connection of the structural elements, etc. shown in the following embodiments are mere examples, and are not intended to limit the scope of the present disclosure. Accordingly, among the structural elements in the following embodiments, structural elements not recited in the independent claims defining the broadest concepts of the present disclosure are described as optional structural elements.

It should be noted that the figures are schematic diagrams and are not necessarily precise illustrations. Further, in the figures, substantially identical elements are assigned the same reference signs, and overlapping description is omitted or simplified.

### Embodiment 1

The following describes a light source according to Embodiment 1.

### [1-1. Schematic Configuration]

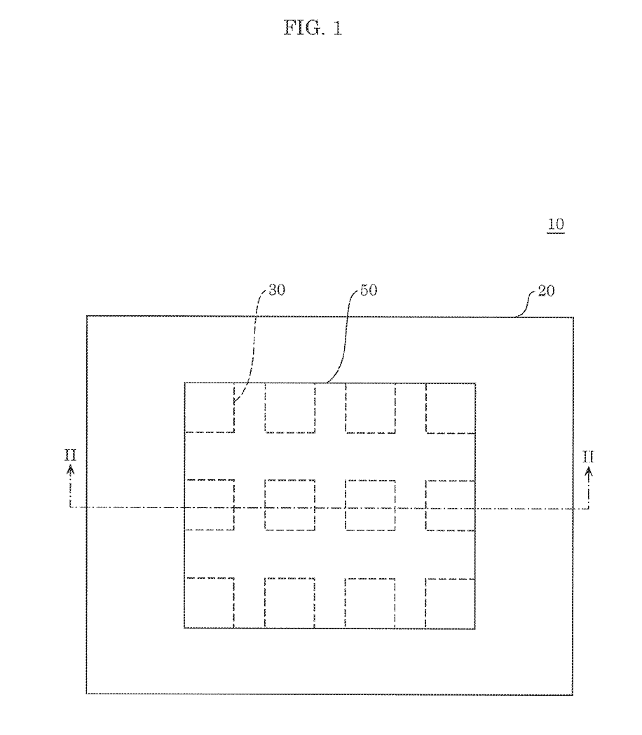

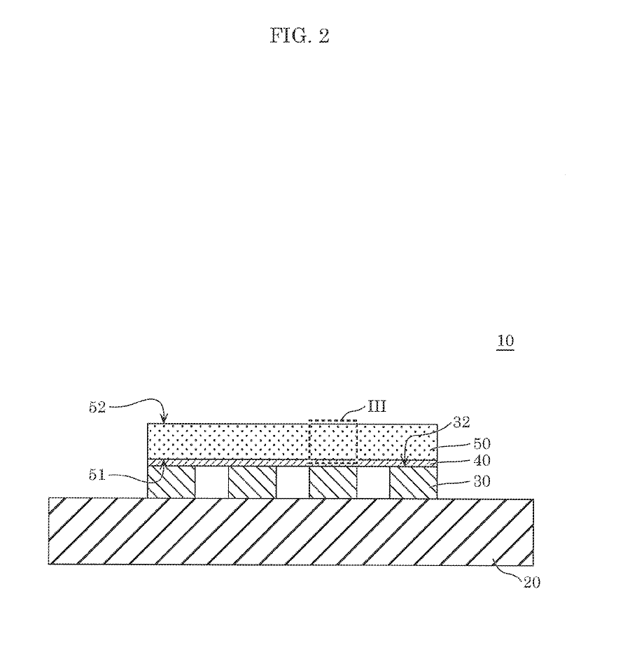

First, the following describes a schematic configuration of the light source according to Embodiment 1 with reference to the drawings. FIG. 1 and FIG. 2 are a schematic plan view of and a schematic cross-sectional diagram illustrating a schematic configuration of light source 10 according to Embodiment 1, respectively. FIG. 2 shows a cross-section taken along line II-II in FIG. 1.

Light source 10 according to Embodiment 1 is a light-emitting device that emits white light having high color rendering properties, and is used in a light projector, an illumination device installed to a high ceiling, and a vehicle headlamp, etc.

The white light emitted by light source 10 has a correlated color temperature of at least 2700 K and at most 7200 K, chromaticity deviation Duv within ±10, and average color rendering index Ra of at least 80. Such properties of the white light emitted by light source 10 can reduce a difference between a color shade of an object illuminated with the white light and a color shade of the object illuminated with natural light. Accordingly, applying light source 10 to an illumination device used in a factory allows more accurate visual confirmation of a color shade of a product manufactured in the factory. Applying light source 10 to a vehicle headlamp allows more accurate identification of an illuminated object. Applying light source 10 to the light projector allows a reduction in a sense of discomfort associated with a color shade of an illuminated object.

The white light emitted by light source 10 may have a correlated color temperature of at least 2700 K and at most 6500 K. This can further reduce the difference between the color shade of the object illuminated with the white light and the color shade of the object illuminated with the natural light.

As shown in FIG. 2, light source 10 includes solid-state light emitter 30, fluorescent layer 50, and light-transmissive adhesive 40. As shown in FIG. 1 and FIG. 2, light source 10 further includes substrate 20.

Substrate 20 is a mounting substrate for mounting solid-state light emitter 30 of light source 10, and has a mounting face on which a conductive pattern is formed. Here, the conductive pattern is a patterned conductive component. Examples of substrate 20 include a ceramic substrate, a resin substrate, and a metal base substrate covered in an insulating film.

Solid-state light emitter 30 is a light-emitting element to be mounted on substrate 20 on which the conductive pattern is formed. In Embodiment 1, solid-state light emitter 30 is an LED chip that has light-emitting face 32 and emits blue light from light-emitting face 32. Solid-state light emitter 30 has a peak wavelength of at least 430 nm. This can arrest decline of average color rendering index Ra. Further, solid-state light emitter 30 may have a peak wavelength of at least 445 nm. This can further arrest the decline of average color rendering index Ra. In addition, solid-state light emitter 30 has a peak wavelength of at most 460 nm. This can arrest a decline in luminous efficacy of solid-state light emitter 30.

Light source 10 may include at least one solid-state light emitter 30, and the number of solid-state light emitters 30 to be included in light source 10 may be appropriately determined according to an intensity of emitted light required for light source 10.

Fluorescent layer 50 is a wavelength converter that is disposed on light-emitting face 32 of solid-state light emitter 30, and emits light having a wavelength different from a wavelength of light from solid-state light emitter 30, by being excited by the light from solid-state light emitter 30. Fluorescent layer 50 has first face 51 facing light-emitting face 32 of solid-state light emitter 30, and second face 52 on a backside of first face 51. In other words, fluorescent layer 50 has first face 51 and second face 52 in a position opposite first face 51. Fluorescent layer 50 will be described in detail later.

Light-transmissive adhesive 40 is a light-transmissive plate that bonds light-emitting face 32 of solid-state light emitter 30 and first face 51 of fluorescent layer 50 facing light-emitting face 32. Light-transmissive adhesive 40 is a light-transmissive resin such as a silicone resin that absorbs less light in a visible range (of at least 380 nm and at most 780 nm). Light-transmissive adhesive 40 may be reduced in thickness within a scope in which bonding strength can be ensured. Light-transmissive adhesive 40 may have a thickness of more than 0 μm and at most 10 μm. This can accelerate conduction of heat generated in fluorescent layer 50 to solid-state light emitter 30. As a result, it is possible to arrest a decline in wavelength conversion efficiency in fluorescent layer 50 which results from the rise in temperature of fluorescent layer 50. In Embodiment 1, light-transmissive adhesive 40 has a thickness of approximately 5 μm.

Light-transmissive adhesive 40 may have an elastic modulus of at most 3.0 MPa. With this, when heat is suddenly generated in light source 10, it is possible to reduce deformation occurring between solid-state light emitter 30 and fluorescent layer 50. For this reason, it is possible to reduce the occurrence of a crack in fluorescent layer 50. Moreover, an inorganic filler having a refractive index different from a refractive index of light-transmissive adhesive 40 may be added to light-transmissive adhesive 40. Consequently, since the inorganic filler can diffuse light from solid-state light emitter 30, it is possible to homogenize an intensity distribution of light incident on first face 51 of fluorescent layer 50.

### [1-2. Detailed Configuration of Fluorescent Layer]

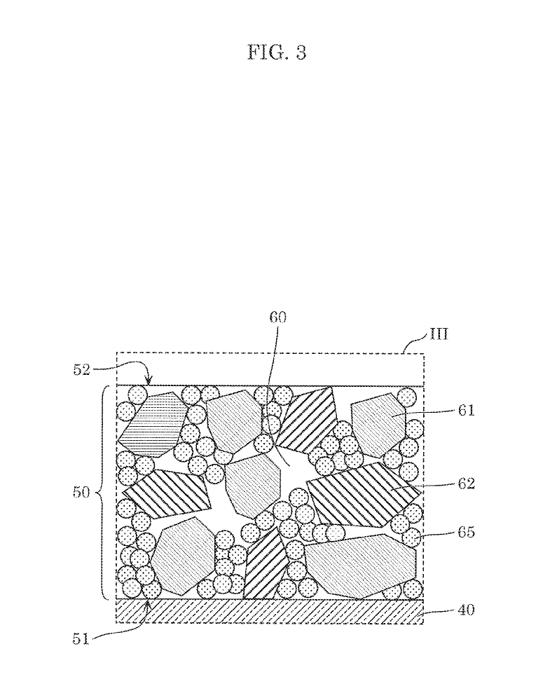

The following describes a detailed configuration of fluorescent layer 50 of Embodiment 1 with reference to the drawings. FIG. 3 is a schematic cross-sectional diagram illustrating the detailed configuration of fluorescent layer 50 according to Embodiment 1. FIG. 3 is an enlarged view of region III outlined by a broken line in FIG. 2.

Fluorescent layer 50 includes fluorescent materials of two or more types different in emission peak wavelength, binder 65, and void 60.

In Embodiment 1, as shown in FIG. 3, fluorescent layer 50 includes fluorescent materials of two types, that is, first fluorescent material 61 and second fluorescent material 62. First fluorescent material 61 is a green fluorescent material or yellow-green fluorescent material such as a YAG fluorescent material, a LuAG (Lu₃A₅O₁₂:Ce³⁺) fluorescent material, a silicate fluorescent material, and an oxynitride fluorescent material. Second fluorescent material 62 is a red fluorescent material such as a nitride fluorescent material and an oxynitride fluorescent material. Because fluorescent layer 50 of light source 10 according to Embodiment 1 includes the fluorescent materials of two or more types different in emission peak wavelength, it is possible to adjust properties such as a correlated color temperature, chromaticity deviation Duv, and average color rendering index Ra of white light emitted from light source 10 to be desired values. Specifically, it is possible to adjust the properties of the white light emitted from light source 10, by controlling the wavelength of light emitted from solid-state light emitter 30, the emission peak wavelength of each of the fluorescent materials: and a mixing ratio of the fluorescent materials in fluorescent layer 50. In particular, it is possible to increase average color rendering index Ra of the white light by the fluorescent materials including the green fluorescent material or yellow-green fluorescent material, and the red fluorescent material.

Binder 65 is a component that includes a light-transmissive inorganic compound that fixes a fluorescent material. In Embodiment 1, binder 65 is an inorganic compound that absorbs less light in a visible range. It is possible to arrest a decline in efficiency of light source 10 by using, as binder 65, a component that absorbs less light in the visible range. Moreover, when high-power light from solid-state light emitter 30 is incident on binder 65, and binder 65 is placed in a high-temperature state, it is possible to reduce degeneration of binder 65 such as coloring, by using the inorganic compound as binder 65. The inorganic compound for use in binder 65 may be a single material of, for example, a semiconductor oxide such as SiO₂ or a metal oxide such as ZnO, ZrO₂, TiO₂, and MgO, or a composite material thereof. Further, binder 65 may include siloxanes, silanols, silanol groups, alkyl groups, etc. that are residues remaining after the fluorescent materials are fixed.

Void 60 is a space formed in a gap between the fluorescent materials and binder 65 in fluorescent layer 50.

Because fluorescent layer 50 includes the fluorescent materials of two or more types, which are components having a high elastic modulus and different coefficients of thermal expansion, and the inorganic compound, when high-power light is incident on fluorescent layer 50 and fluorescent layer 50 is subjected to a high temperature, stress is generated between the fluorescent materials and binder 65. In Embodiment 1, however, because fluorescent layer 50 includes void 60, it is possible to mitigate the stress generated in fluorescent layer 50 using void 60. Thus, it is possible to reduce the occurrence of the crack in fluorescent layer 50.

Void 60 may have a volume proportion of at least 3% and at most 50% in fluorescent layer 50. It is possible to surely mitigate the stress generated in fluorescent layer 50 by setting the volume proportion of void 60 to be at least 3% in fluorescent layer 50. Since it is possible to immediately conduct the heat generated in fluorescent layer 50 to solid-state light emitter 30, by setting the volume proportion of void 60 to be at most 50% in fluorescent layer 50, it is possible to curb the rise in temperature of fluorescent layer 50. As a result, it is possible to arrest the decline in wavelength conversion efficiency which results from the rise in temperature of fluorescent layer 50.

Fluorescent layer 50 may have a thickness of at least 20 μm and at most 80 μm. By setting the thickness of fluorescent layer 50 to be at least 20 μm, a sufficient number of fluorescent materials is included in the thickness direction of fluorescent layer 50 in order to perform wavelength conversion. In other words, it is possible to ensure sufficient wavelength conversion efficiency in fluorescent layer 50. Moreover, since it is possible to immediately conduct the heat generated in fluorescent layer 50 to solid-state light emitter 30 by setting the thickness of fluorescent layer 50 to be at most 80 μm, it is possible to curb the rise in temperature of fluorescent layer 50. As a result, it is possible to arrest the decline in wavelength conversion efficiency which results from the rise in temperature of fluorescent layer 50.

The size of fluorescent layer 50 perpendicular to the thickness direction may be a size that allows fluorescent layer 50 to cover light-emitting face 32 of solid-state light emitter 30. In other words, the size of fluorescent layer 50 may be greater than or equal to the size of light-emitting face 32. This allows most part of light emitted from light-emitting face 32 to be incident on fluorescent layer 50. As with light source 10 according to Embodiment 1, when one fluorescent layer 50 covers all of solid-state light emitters 30, one end of fluorescent layer 50 perpendicular to the thickness direction may be located outward of one end of light-emitting face 32 by approximately at least 50 μm and at most 500 μm. This allows most part of light emitted from light-emitting face 32 to be surely incident on fluorescent layer 50.

Fluorescent layer 50 according to Embodiment 1 is formed by binder 65 fixing the fluorescent materials of two or more types. A sol-gel method, a polysilazane method, etc. can be used for fixing the fluorescent materials by binder 65. Moreover, it is possible to adjust the proportion of void 60 included in fluorescent layer 50 by changing, for example, a proportion of organic solvent in a material in which the fluorescent materials before fixing are included.

The diameter of the fluorescent materials included in fluorescent layer 50 is not particularly limited, but may be at least 5 μm and at most 40 μm. Setting the diameter of the fluorescent materials to be at least 5 μm makes it easy to form void 60 in fluorescent layer 50. Setting the diameter of the fluorescent materials to be at most 40 μm makes it difficult for fluorescent layer 50 to become fragile.

The fluorescent materials included in fluorescent layer 50 may include first particles having a diameter larger than or equal to a first diameter, and second particles having a diameter smaller than the first diameter. In Embodiment 1, the first diameter is 15 μm. An interface of the fluorescent materials inside fluorescent layer 50 is reduced by fluorescent layer 50 including the first particles, which are fluorescent materials having a relatively large diameter. Since this reduces light scattering in fluorescent layer 50, it is possible to arrest a decline in light extraction efficiency in fluorescent layer 50. Moreover, since there are cases where defects are on the surfaces of the fluorescent materials, it is possible to reduce the defects of the fluorescent materials by decreasing the surface area of the fluorescent materials by increasing the diameter of the fluorescent materials. Further, it is possible to arrest a decline in wavelength conversion capacity of the fluorescent materials which results from decreasing the diameter of the fluorescent materials. As stated above, it is possible to arrest the decline in light extraction efficiency and wavelength conversion efficiency in fluorescent layer 50 by fluorescent layer 50 including the first particles, which are the fluorescent materials having the relatively large diameter.

Contact areas between the fluorescent materials and between the fluorescent materials and binder 65 are increased by fluorescent layer 50 including the second particles, which are fluorescent materials having a relatively small diameter. Since this enhances heat dissipation characteristics in fluorescent layer 50, it is possible to curb the rise in temperature of fluorescent layer 50. As a result, it is possible to arrest the decline in wavelength conversion efficiency which results from the rise in temperature of fluorescent layer 50.

In Embodiment 1, for example, the median diameter of the first particles of the fluorescent materials may be at least 15 μm and at most 40 μm, and the median diameter of the second particles of the fluorescent materials may be at least 5 μm and less than 15 μm. In addition, a ratio of the median diameter of the first particles to the median diameter of the second particles may be at least 1.5 and at least 2.5.

It should be noted that the first particles may include of the fluorescent materials different in emission peak wavelength or only the fluorescent materials of one type. As with the first particles, the second particles may include fluorescent materials different in emission peak wavelength or only the fluorescent materials of one type.

### [1-3. Summary]

As described above, light source 10 according to Embodiment 1 is a light source that emits white light. The white light has a correlated color temperature of at least 2700 K and at most 7200 K, chromaticity deviation Duv within ±10, and average color rendering index Ra of at least 80. Light source 10 includes solid-state light emitter 30 that emits light having a first wavelength via light-emitting face 32, and fluorescent layer 50 that has first face 51 facing solid-state light emitter 30 and second face 52 positioned across from the first face, receives, via first face 51, the light emitted by solid-state light emitter 30, and transmits, via second face 52, light having a second wavelength different from the first wavelength, fluorescent layer 50 being excited by the light received from solid-state light emitter 30. Light source 10 further includes light-transmissive adhesive 40 that bonds light-emitting face 32 of solid-state light emitter 30 and first face 51 of fluorescent layer 50. Fluorescent layer 50 includes: first fluorescent material 61 of a first type having a first emission peak wavelength, and second fluorescent material 62 of a second type having a second emission peak wavelength; binder 65 that includes a light-transmissive inorganic compound that fixes first fluorescent material 61 and second fluorescent material 62; and void 60 that is provided between first fluorescent material 61 and second fluorescent material 62.

In light source 10, fluorescent layer 50 includes the fluorescent materials of two or more types different in emission peak wavelength, and thus it is possible to adjust properties such as a correlated color temperature, chromaticity deviation Duv, and average color rendering index Ra of white light emitted from light source 10 to be desired values. Accordingly, light source 10 can emit white light with high color rendering properties which has a correlated color temperature of at least 2700 K and at most 7200 K, chromaticity deviation Duv within ±10, and average color rendering index Ra of at least 80. Moreover, because binder 65 included in fluorescent layer 50 includes an inorganic compound, when high-power light from solid-state light emitter 30 is incident on binder 65, and binder 65 is placed in a high-temperature state, it is possible to reduce degeneration of binder 65 such as coloring. As a result, it is possible to provide light source 10 that is high-powered. Furthermore, light source 10 includes solid-state light emitter 30 such as an LED chip, and thus it is possible to provide light source 10 that is compact. Fluorescent layer 50 includes the fluorescent materials of two or more types, which are components having a high elastic modulus and different coefficients of thermal expansion, and the inorganic compound. Fluorescent layer 50, however, includes void 60, and thus it is possible to mitigate stress generated in fluorescent layer 50 via void 60. Accordingly, it is possible to reduce the occurrence of a crack in fluorescent layer 50. In other words, it is possible to improve durability of light source 10.

Moreover, in light source 10, first fluorescent material 61 may include first particles having a diameter larger than or equal to a first diameter, and second fluorescent material 62 may include second particles having a diameter smaller than the first diameter.

An interface of the fluorescent materials inside fluorescent layer 50 is reduced by fluorescent layer 50 including the first particles, which are fluorescent materials having a relatively large diameter. Since this reduces light scattering in fluorescent layer 50, it is possible to arrest a decline in light extraction efficiency in fluorescent layer 50. Moreover, since there are cases where defects are on the surfaces of the fluorescent materials, it is possible to reduce the defects of the fluorescent materials by decreasing the surface area of the fluorescent materials by increasing the diameter of the fluorescent materials. Further, it is possible to arrest a decline in wavelength conversion capacity of the fluorescent materials which results from decreasing the diameter of the fluorescent materials. As stated above, it is possible to arrest the decline in light extraction efficiency and wavelength conversion efficiency in fluorescent layer 50 by fluorescent layer 50 including the first particles, which are the fluorescent materials having the relatively large diameter. Contact areas between the fluorescent materials and between the fluorescent materials and binder 65 are increased by fluorescent layer 50 including the second particles, which are fluorescent materials having a relatively small diameter. Since this enhances heat dissipation characteristics in fluorescent layer 50, it is possible to curb the rise in temperature of fluorescent layer 50. As a result, it is possible to arrest the decline in wavelength conversion efficiency which results from the rise in temperature of fluorescent layer 50.

Moreover, in light source 10, void 60 may have a volume proportion of at least 3% and at most 50% in fluorescent layer 50.

It is possible to surely mitigate the stress generated in fluorescent layer 50 by setting the volume proportion of void 60 to be at least 3% in fluorescent layer 50. Since it is possible to immediately conduct the heat generated in fluorescent layer 50 to solid-state light emitter 30, by setting the volume proportion of void 60 to be at most 50% in fluorescent layer 50, it is possible to curb the rise in temperature of fluorescent layer 50. As a result, it is possible to arrest the decline in wavelength conversion efficiency which results from the rise in temperature of fluorescent layer 50.

Moreover, in light source 10, fluorescent layer 50 may have a thickness of at least 20 μm and at most 80 μm.

By setting the thickness of fluorescent layer 50 to be at least 20 μm, a sufficient number of fluorescent materials is included in the thickness direction of fluorescent layer 50 in order to perform wavelength conversion. In other words, it is possible to ensure sufficient wavelength conversion efficiency in fluorescent layer 50. Moreover, since it is possible to immediately conduct the heat generated in fluorescent layer 50 to solid-state light emitter 30 by setting the thickness of fluorescent layer 50 to be at most 80 μm, it is possible to curb the rise in temperature of fluorescent layer 50. As a result, it is possible to arrest the decline in wavelength conversion efficiency which results from the rise in temperature of fluorescent layer 50.

### [1-4. Variation]

The following describes a light source according to a variation of Embodiment 1. The light source according to the variation has the same configuration as above-described light source 10, except that a separate fluorescent layer is disposed for each solid-state light emitter 30. Hereinafter, the light source according to the variation will be described with reference to the drawings, with a focus on the differences from above-described light source 10.

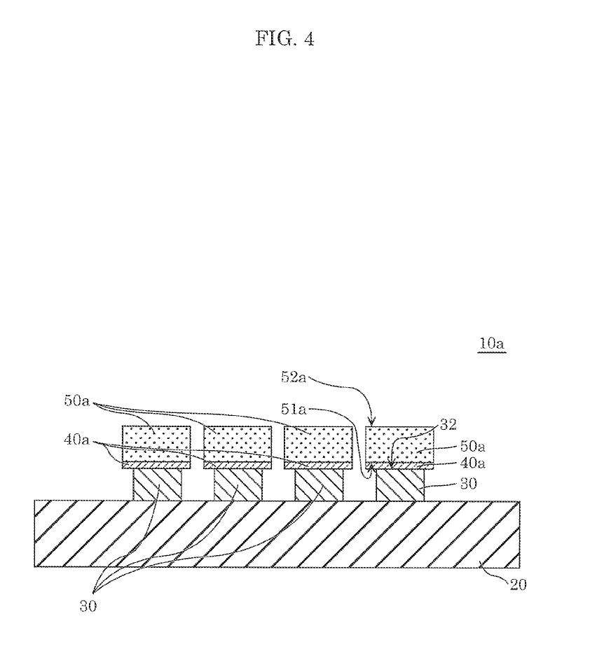

FIG. 4 is a schematic cross-sectional diagram illustrating a schematic configuration of light source 10a according to the variation. FIG. 4 shows a cross-section similar to the cross-section of light source 10 shown in FIG. 2. As shown in FIG. 4, light source 10a according to the variation includes substrate 20, solid-state light emitters 30, light-transmissive adhesives 40a, and fluorescent layers 50a.

Fluorescent layers 50a are respectively disposed above solid-state light emitters 30. Each of fluorescent layers 50a has first face 51a facing light-emitting face 32 of corresponding solid-state light emitter 30, and second face 52a on a backside of first face 51a. Each of light-transmissive adhesives 40a bonds light-emitting face 32 of corresponding solid-state light emitter 30 and first face 51a of corresponding fluorescent layer 50a facing light-emitting face 32. In other words, light source 10a includes the same number of fluorescent layers 50a and light-transmissive adhesives 40a as the number of solid-state light emitters 30.

As with above-described fluorescent layer 50, the size of fluorescent layers 50a perpendicular to a thickness direction of fluorescent layers 50a may be a size that allows fluorescent layers 50a to cover light-emitting faces 32 of solid-state light emitters 30. In other words, the size of fluorescent layers 50a may be greater than or equal to the size of light-emitting faces 32. This allows most part of light emitted from light-emitting faces 32 to be incident on fluorescent layers 50a. Moreover, one end of each fluorescent layer 50a perpendicular to the thickness direction may be located outward of one end of corresponding light-emitting face 32 by approximately at least 50 μm and at most 500 μm. To put it differently, the size of fluorescent layers 50a perpendicular to the thickness direction may be larger than the size of light-emitting faces 32 perpendicular to the thickness direction by approximately at least 100 μm and at most 500 μm. This allows most part of light emitted from light-emitting faces 32 to be surely incident on fluorescent layers 50a.

Light source 10a according to the variation having the above configuration produces the same advantageous effects as above-described light source 10.

### Embodiment 2

The following describes a light source according to Embodiment 2. The light source according to Embodiment 2 has the same configuration as light source 10 according to Embodiment 1, except that the light source according to Embodiment 2 further includes a light-transmissive plate on a fluorescent layer. Hereinafter, the light source according to Embodiment 2 will be described with reference to the drawings, with a focus on the differences from light source 10 according to Embodiment 1.

### [2-1. Schematic Configuration]

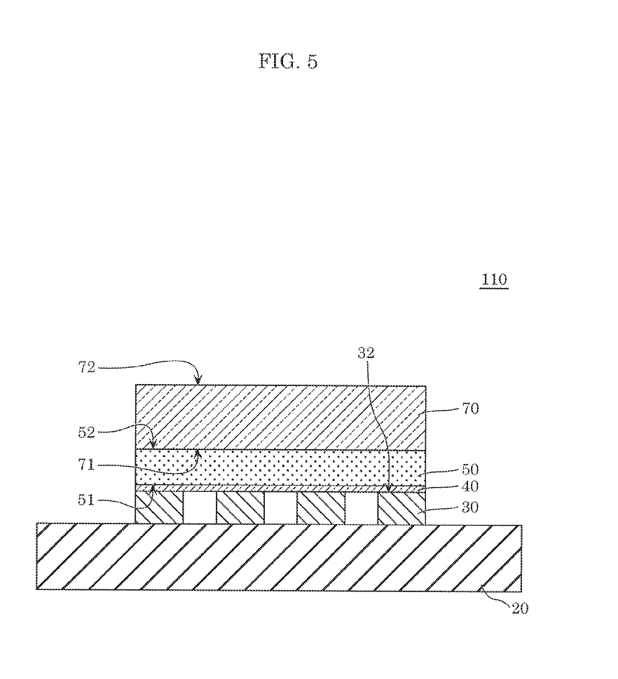

FIG. 5 is a schematic cross-sectional diagram illustrating a schematic configuration of light source 110 according to Embodiment 2. FIG. 5 shows a cross-section similar to the cross-section of light source 10 shown in FIG. 2. As shown in FIG. 5, as with light source 10 according to Embodiment 1, light source 110 according to Embodiment 2 includes substrate 20, solid-state light emitter 30, light-transmissive adhesive 40, and fluorescent layer 50. Light source 110 according to Embodiment 2 further includes light-transmissive plate 70.

Substrate 20, solid-state light emitter 30, light-transmissive adhesive 40, and fluorescent layer 50 according to Embodiment 2 are the same in configuration as substrate 20, solid-state light emitter 30, light-transmissive adhesive 40, and fluorescent layer 50 according to Embodiment 1.

### [2-2. Light-Transmissive Plate]

Light-transmissive plate 70 is a component on second face 52 on a backside of first face 51 in fluorescent layer 50. In Embodiment 2, light-transmissive plate 70 is a plate-shaped component having entrance face 71 facing second face 52 of fluorescent layer 50, and exit face 72 on a backside of entrance face 71. In other words, light-transmissive plate 70 has entrance face 71 and exit face 72 in a position opposite entrance face 71. Entrance face 71 of light-transmissive plate 70 is a face on which light emitted from fluorescent layer 50 is incident. Exit face 72 of light-transmissive plate 70 is a face from which light incident on light-transmissive plate 70 exits. Light-transmissive plate 70 is, for example, an inorganic that absorbs less light in the visible range, and may specifically be a glass plate, a quartz glass plate, etc.

Light-transmissive plate 70 has a function of protecting fluorescent layer 50. Although fluorescent layer 50 is fragile because of void 60 and may be cracked or broken by externally generated stress such as scratching, fluorescent layer 50 can be protected from the externally generated stress by disposing light-transmissive plate 70 on fluorescent layer 50.

Light-transmissive plate 70 may have a refractive index close to a refractive index of binder 65 included in fluorescent layer 50. Specifically, a difference in refractive index between light-transmissive plate 70 and binder 65 included in fluorescent layer 50 may be at most 0.2. This can reduce, of light emitted from fluorescent layer 50 to the interface between fluorescent layer 50 and light-transmissive plate 70, components reflected by the interface. Accordingly, it is possible to increase the light extraction efficiency of light source 110. Moreover, a silane coupling treatment may be performed between light-transmissive plate 70 and binder 65 included in fluorescent layer 50. This can enhance adhesion between fluorescent layer 50 and binder 65.

Exit face 72 of light-transmissive plate 70 is roughened, and may be a rough face having an arithmetic surface roughness (average surface roughness) of at least 50 nm. This can reduce, of light emitted to exit face 72, components reflected by the interface between exit face 72 and the outside. Accordingly, it is possible to increase the light extraction efficiency of light source 110.

When light-transmissive plate 70 is included in the same manner as light source 110 according to Embodiment 2, fluorescent layer 50 may be directly formed on entrance face 71 of light-transmissive plate 70. When fluorescent layer 50 formed on light-transmissive plate 70 is mounted on light-emitting face 32 of solid-state light emitter 30 via light-transmissive adhesive 40, light-transmissive plate 70 can be pressed against solid-state light emitter 30. Here, it is possible to minimize the thickness of light-transmissive adhesive 40 by pressing light-transmissive plate 70 against solid-state light emitter 30 with sufficient force. Since this can minimize thermal resistance between fluorescent layer 50 and solid-state light emitter 30, it is possible to curb the rise in temperature of fluorescent layer 50. As a result, it is possible to arrest the decline in wavelength conversion efficiency which results from the rise in temperature of fluorescent layer 50.

The thickness of light-transmissive plate 70, that is, a distance between entrance face 71 and exit face 72, is appropriately set according to the size etc. of solid-state light emitter 30. Light-transmissive plate 70 may have a thickness of, for example, at least 50 m and at most 1 mm. It is possible to ensure sufficient strength to protect fluorescent layer 50 by setting the thickness of light-transmissive plate 70 to be at least 50 μm. It is possible to reduce components of light exiting from a lateral face etc. other than exit face 72, by setting the thickness of light-transmissive plate 70 to be at most 1 mm.

The size of light-transmissive plate 70 perpendicular to the thickness direction of light-transmissive plate 70 may be a size that allows light-transmissive plate 70 to cover second face 52 of fluorescent layer 50. This allows most part of light emitted from second face 52 to be incident on light-transmissive plate 70.

### [2-3. Summary]

As described above, light source 110 according to Embodiment 2 may further include light-transmissive plate 70 that is disposed on second face 52 of fluorescent layer 50.

This makes it possible to protect fluorescent layer 50 from externally generated stress. In addition, fluorescent layer 50 can be directly formed in light-transmissive plate 70 by light source 110 including light-transmissive plate 70. When fluorescent layer 50 formed on light-transmissive plate 70 is mounted on light-emitting face 32 of solid-state light emitter 30 via light-transmissive adhesive 40, light-transmissive plate 70 can be pressed against solid-state light emitter 30. Here, it is possible to minimize the thickness of light-transmissive adhesive 40 by pressing light-transmissive plate 70 against solid-state light emitter 30 with sufficient force. Since this can minimize thermal resistance between fluorescent layer 50 and solid-state light emitter 30, it is possible to curb the rise in temperature of fluorescent layer 50. As a result, it is possible to arrest the decline in wavelength conversion efficiency which results from the rise in temperature of fluorescent layer 50.

Moreover, in light source 110, exit face 72 of light-transmissive plate 70 may have an arithmetic average surface roughness of at least 50 nm, exit face being positioned across from entrance face 71 of light-transmissive plate 70 facing fluorescent layer 50.

This can reduce, of light emitted to exit face 72, components reflected by the interface between exit face 72 and the outside. Accordingly, it is possible to increase the light extraction efficiency of light source 110.

### [2-4. Variation]

Next, the following describes a light source according to a variation of Embodiment 2. The light source according to the variation has the same configuration as light source 110, except that the light source according to the variation includes an antireflection film on an exit face instead of the roughened exit face of the light-transmissive plate. Hereinafter, the light source according to the variation will be described with reference to the drawings, with a focus on the differences from above-described light source 110.

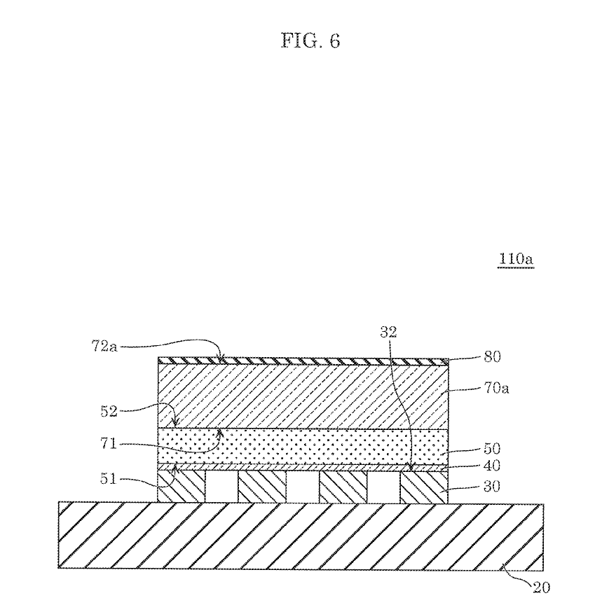

FIG. 6 is a schematic cross-sectional diagram illustrating a schematic configuration of light source 110a according to the variation. FIG. 6 shows a cross-section similar to the cross-section of light source 10 shown in FIG. 2. As shown in FIG. 6, light source 110a according to the variation includes substrate 20, solid-state light emitters 30, light-transmissive adhesive 40, fluorescent layer 50, light-transmissive plate 70a, and antireflection film 80.

Light-transmissive plate 70a is a component on second face 52 on a backside of first face 51 in fluorescent layer 50. In the variation, light-transmissive plate 70a is a plate-shaped component having entrance face 71 facing second face 52 of fluorescent layer 50, and exit face 72a on a backside of entrance face 71. Exit face 72a of light-transmissive plate 70a according to the variation is not roughened.

Antireflection film 80 is a film disposed on exit face 72a of light-transmissive plate 70a in the position opposite entrance face 71 facing fluorescent layer 50. Antireflection film 80 reduces, of light emitted to exit face 72a, reflection components in the interface between exit face 72a and the outside. In other words, antireflection film 80 reduces a reflectance of the interface in the visible range. Antireflection film 80 may include, for example, a dielectric multilayer.

As stated above, light source 110a according to the variation includes antireflection film 80 disposed on exit face 72a of light-transmissive plate 70a in the position opposite entrance face 71 facing fluorescent layer 50. Consequently, light source 110a according to the variation produces the same advantageous effects as light source 110 according to Embodiment 2.

### Embodiment 3

The following describes a light source according to Embodiment 3. The light source according to Embodiment 3 has the same configuration as light source 110 according to Embodiment 2, except for a fluorescent layer. Hereinafter, the light source according to Embodiment 3 will be described with reference to the drawings, with a focus on the differences from light source 110 according to Embodiment 2.

### [3-1. Schematic Configuration]

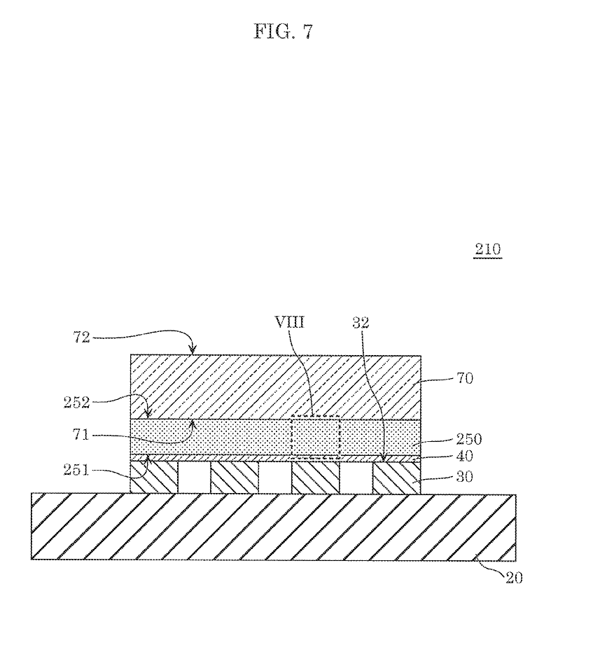

FIG. 7 is a schematic cross-sectional diagram illustrating a schematic configuration of light source 210 according to Embodiment 3. FIG. 7 shows a cross-section similar to the cross-section of light source 10 shown in FIG. 2. As shown in FIG. 7, as with light source 110 according to Embodiment 2, light source 210 according to Embodiment 3 includes substrate 20, solid-state light emitter 30, light-transmissive adhesive 40, fluorescent layer 50, and light-transmissive plate 70.

Substrate 20, solid-state light emitter 30, light-transmissive adhesive 40, and light-transmissive plate 70 according to Embodiment 3 are the same in configuration as substrate 20, solid-state light emitter 30, light-transmissive adhesive 40, and light-transmissive plate 70 according to Embodiment 2.

### [3-2. Fluorescent Layer]

As with fluorescent layer 50 according to Embodiment 1 or Embodiment 2, fluorescent layer 250 according to Embodiment 3 is a wavelength converter that is disposed on light-emitting face 32 of solid-state light emitter 30, and emits light having a wavelength different from a wavelength of light from solid-state light emitter 30, by being excited by the light from solid-state light emitter 30. Fluorescent layer 250 has first face 251 facing light-emitting face 32 of solid-state light emitter 30, and second face 252 on a backside of first face 251.

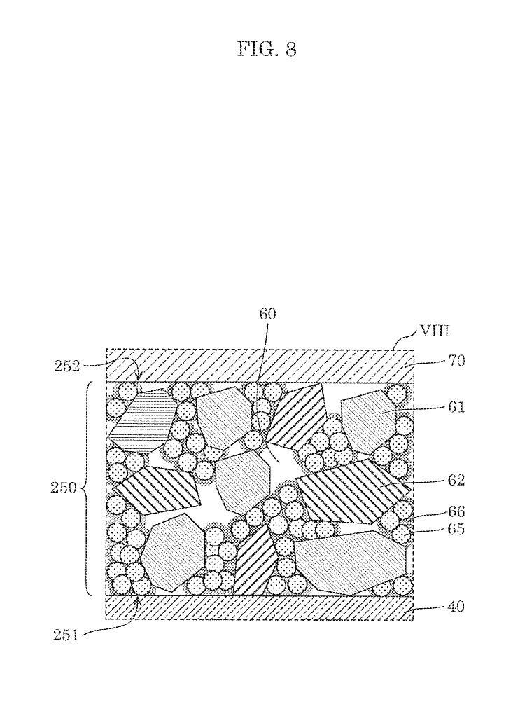

The following describes a detailed configuration of fluorescent layer 250 with reference to the drawings. FIG. 8 is a schematic cross-sectional diagram illustrating the detailed configuration of fluorescent layer 250 according to Embodiment 3. FIG. 8 is an enlarged view of region VIII outlined by a broken line in FIG. 7.

As with fluorescent layer 50 according to Embodiment 2, fluorescent layer 250 includes fluorescent materials of two or more types different in emission peak wavelength, binder 65, and void 60. Fluorescent layer 250 includes fluorescent materials of two types, that is, first fluorescent material 61 and second fluorescent material 62.

In Embodiment 3, fluorescent layer 250 further includes light-transmissive coating layer 66 that covers binder 65 and is made of a material different from the material of binder 65. When such coating layer 66 is included, the fluorescent materials in fluorescent layer 250 are bonded by coating layer 66 in addition to binder 65. This can enhance adhesion between the fluorescent materials. Since this can increase the strength of fluorescent layer 250, it is possible to reduce the occurrence of missing of fluorescent layer 250 and a crack in fluorescent layer 250 when fluorescent layer 250 is produced and mounted on solid-state light emitter 30.

Coating layer 66 is made of a light-transmissive material that absorbs less light in the visible range. Coating layer 66 is made of an organic-inorganic hybrid material such as liquid glass and silsesquioxane, a resin material such as silicone resin, etc.

A difference in refractive index between coating layer 66 and binder 65 may be at most 0.15. Since this can reduce a refractive index interface around the fluorescent materials, it is possible to reduce light scattering in fluorescent layer 250. This allows light incident on fluorescent layer 250 to reach inside fluorescent layer 250. Accordingly, it is possible to increase wavelength conversion efficiency in fluorescent layer 250. In addition, it is possible to increase extraction efficiency for light wavelength-converted by the fluorescent materials, by reducing the light scattering in fluorescent layer 250.

Coating layer 66 may have a thickness of at least 0.2 μm and at most 20 μm. It is possible to surely produce the above-described effects of coating layer 66 by setting the thickness of coating layer 66 to be at least 0.2 μm. It is possible to reduce the occurrence of the crack in fluorescent layer 250 which results from the formation of coating layer 66, by setting the thickness of coating layer 66 to be at most 20 μm.

Although coating layer 66 is uniformly arranged across fluorescent layer 250 in Embodiment 3, the arrangement of coating layer 66 need not be uniform. For example, a proportion of coating layer 66 in fluorescent layer 250 may be higher with decreasing distance to solid-state light emitter 30. Accordingly, it is possible to increase the strength of fluorescent layer 250 in a region of fluorescent layer 250 neighboring solid-state light emitter 30.

Moreover, when the difference in refractive index between coating layer 66 and binder 65 is at most 0.15, it is possible to reduce light scattering by increasing the proportion of coating layer 66 in the region of fluorescent layer 250 neighboring solid-state light emitter 30. This allows light from solid-state light emitter 30 and incident on fluorescent layer 250 to reach inside fluorescent layer 250. Accordingly, it is possible to increase the wavelength conversion efficiency in fluorescent layer 250.

In contrast, coating layer 66 reduces a proportion of void 60 in fluorescent layer 250, and thus a lower proportion of coating layer 66 is better from a standpoint of stress mitigation. Accordingly, it is possible to both increase the strength of fluorescent layer 250 and mitigate stress by setting the proportion of coating layer 66 to be higher with decreasing distance to solid-state light emitter 30. Furthermore, when light source 210 includes light-transmissive plate 70, it is possible to mitigate stress generated in an interface between light-transmissive plate 70 and fluorescent layer 250 having different coefficients of thermal expansion, by reducing a proportion of coating layer 66 on a side facing light-transmissive plate 70 (a side facing second face 252) in fluorescent layer 250. Thus, it is possible to reduce the occurrence of the crack in fluorescent layer 250.

The proportion of coating layer 66 in fluorescent layer 250 may be continuously or gradually reduced with increasing distance from a position close to solid-state light emitter 30.

A method of forming coating layer 66 is not particularly limited. For example, coating layer 66 may be formed by impregnating a fluorescent layer with a coating liquid obtained by diluting liquid glass with isopropyl alcohol etc., and desolvating and drying the fluorescent layer. Moreover, the proportion of coating layer 66 in fluorescent layer 250 can be adjusted by, for example, a dilute concentration of the coating liquid. Furthermore, coating layers 66 having different proportions in fluorescent layer 250 can be formed by impregnating fluorescent layer 250 with each of coating liquids having different dilute concentrations through a corresponding one of first face 251 and second face 252.

### [3-3. Summary]

As described above, in light source 210 according to Embodiment 3, fluorescent layer 250 may further include light-transmissive coating layer 66 that covers binder 65 and is made of a material different from the material of binder 65.

Since this can increase the strength of fluorescent layer 250, it is possible to reduce the occurrence of missing of fluorescent layer 250 and a crack in fluorescent layer 250 when fluorescent layer 250 is produced and mounted on solid-state light emitter 30.

Moreover, in light source 210, a proportion of coating layer 66 in fluorescent layer 250 may be higher with decreasing distance to solid-state light emitter 30.

Accordingly, it is possible to both increase the strength of fluorescent layer 250 and mitigate the stress. In addition, when light source 210 includes light-transmissive plate 70, it is possible to mitigate the stress generated in the interface between light-transmissive plate 70 and fluorescent layer 250 having different coefficients of thermal expansion, and reduce the occurrence of the crack in fluorescent layer 250.

Moreover, in light source 210, a difference in refractive index between coating layer 66 and binder 65 may be at most 0.15.

This allows light from solid-state light emitter 30 and incident on fluorescent layer 250 to reach inside fluorescent layer 250. Accordingly, it is possible to increase the wavelength conversion efficiency in fluorescent layer 250.

### Embodiment 4

The following describes a light source according to Embodiment 4. The light source according to Embodiment 4 has the same configuration as light source 210 according to Embodiment 3, except for a fluorescent layer. Hereinafter, the light source according to Embodiment 4 will be described with reference to the drawings, with a focus on the differences from light source 210 according to Embodiment 3.

### [4-1. Schematic Configuration]

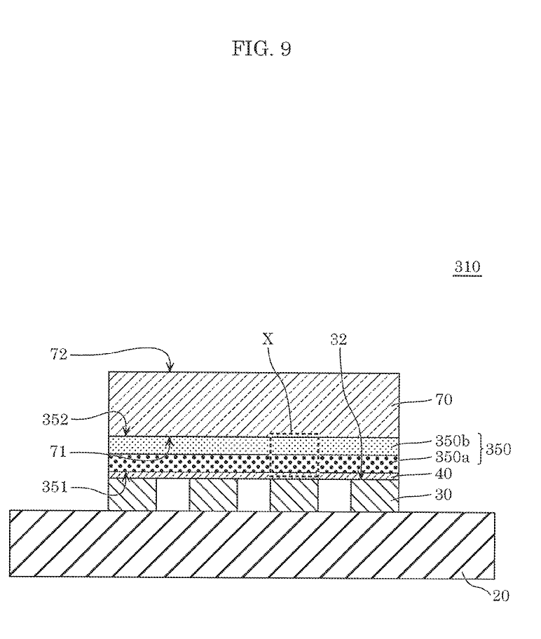

FIG. 9 is a schematic cross-sectional diagram illustrating a schematic configuration of light source 310 according to Embodiment 4. FIG. 9 shows a cross-section similar to the cross-section of light source 10 shown in FIG. 2. As shown in FIG. 9, as with light source 210 according to Embodiment 3, light source 310 according to Embodiment 4 includes substrate 20, solid-state light emitter 30, light-transmissive adhesive 40, fluorescent layer 350, and light-transmissive plate 70.

Substrate 20, solid-state light emitter 30, light-transmissive adhesive 40, and light-transmissive plate 70 according to Embodiment 4 are the same in configuration as substrate 20, solid-state light emitter 30, light-transmissive adhesive 40, and light-transmissive plate 70 according to Embodiment 3.

### [4-2. Fluorescent Layer]

As with fluorescent layer 250 according to Embodiment 3, fluorescent layer 350 according to Embodiment 4 is a wavelength converter that is disposed on light-emitting face 32 of solid-state light emitter 30, and emits light having a wavelength different from a wavelength of light from solid-state light emitter 30, by being excited by the light from solid-state light emitter 30. Fluorescent layer 350 has first face 351 facing light-emitting face 32 of solid-state light emitter 30, and second face 352 on a backside of first face 351.

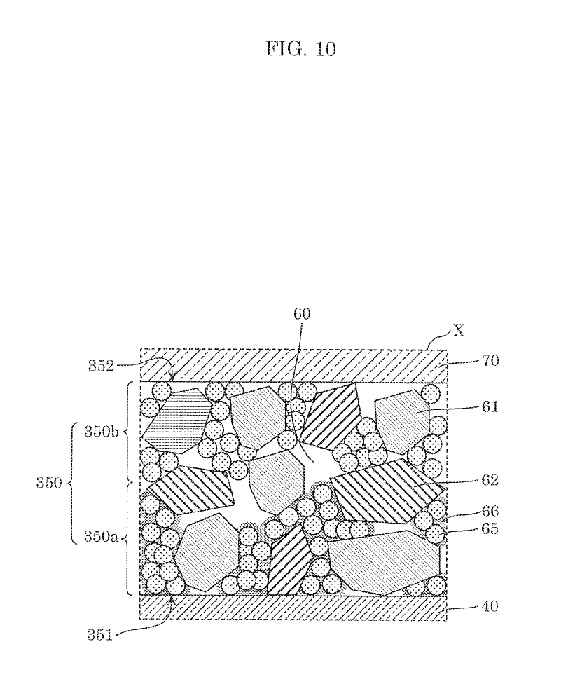

In Embodiment 4, fluorescent layer 350 includes first region 350a and second region 350b. The following describes a detailed configuration of fluorescent layer 350 with reference to the drawings. FIG. 10 is a schematic cross-sectional diagram illustrating the detailed configuration of fluorescent layer 350 according to Embodiment 4. FIG. 10 is an enlarged view of region X outlined by a broken line in FIG. 9.

As with fluorescent layer 250 according to Embodiment 3, first region 350a and second region 350b of fluorescent layer 350 each include fluorescent materials of two or more types different in emission peak wavelength, binder 65, and void 60. First region 350a and second region 350b of fluorescent layer 350 include the fluorescent materials of two types, that is, first fluorescent material 61 and second fluorescent material 62.

In Embodiment 4, as with fluorescent layer 250 according to Embodiment 3, first region 350a of fluorescent layer 350 further includes light-transmissive coating layer 66 that covers binder 65 and is made of a material different from the material of binder 65. In contrast, as with fluorescent layer 50 according to Embodiment 2, second region 350b of fluorescent layer 350 does not include coating layer 66.

In other words, in Embodiment 4, fluorescent layer 350 includes light-transmissive coating layer 66 that covers binder 65 and is made of the material different from the material of binder 65, and coating layer 66 is disposed in a region including first face 351 of fluorescent layer 350. In addition, coating layer 66 is not disposed in a region including at least part of second face 352. To put it differently, fluorescent layer 350 includes first region 350a that is disposed on a side facing first face 351 and includes coating layer 66, and second region 350b that is disposed on a side facing second face 352 and does not include coating layer 66.

Since this can enhance adhesion between the fluorescent materials by coating layer 66 in first region 350a of fluorescent layer 350, it is possible to increase the strength of fluorescent layer 350. Moreover, when the difference in refractive index between coating layer 66 and binder 65 is at most 0.15, it is possible to reduce light scattering in first region 350a. This allows light from solid-state light emitter 30 and incident on fluorescent layer 350 to reach inside fluorescent layer 350. Accordingly, it is possible to increase the wavelength conversion efficiency in fluorescent layer 350.

In contrast, since a proportion of void 60 in second region 350b of fluorescent layer 350 can be increased, it is possible to mitigate stress of fluorescent layer 350. Accordingly, in Embodiment 4, it is possible to both increase the strength of fluorescent layer 350 and mitigate the stress. Moreover, when light source 310 includes light-transmissive plate 70, since coating layer 66 is not formed on a side facing light-transmissive plate 70 in fluorescent layer 350 (a side facing second face 352), void 60 makes it possible to mitigate stress generated in an interface between light-transmissive plate 70 and fluorescent layer 350 having different coefficients of thermal expansion. Thus, it is possible to reduce the occurrence of the crack in fluorescent layer 350.

Furthermore, a proportion of coating layer 66 in second region 350b of fluorescent layer 350 need not be uniform, and may be higher with decreasing distance to solid-state light emitter 30 in the same manner as Embodiment 3.

### [4-3. Summary]

As described above, in light source 310 according to Embodiment 4, fluorescent layer 350 may further include light-transmissive coating layer 66 that covers binder 65 and is made of a material different from the material of binder 65. Coating layer 66 may be disposed in a region including first face 351, and may not be disposed in a region including at least part of second face 352.

Since this can enhance adhesion between the fluorescent materials by coating layer 66 in the region including first face 351 of fluorescent layer 350 (i.e., first region 350a), it is possible to increase the strength of fluorescent layer 350. Moreover, when the difference in refractive index between coating layer 66 and binder 65 is at most 0.15, it is possible to reduce light scattering in first region 350a. This allows light from solid-state light emitter 30 and incident on fluorescent layer 350 to reach inside fluorescent layer 350. Accordingly, it is possible to increase the wavelength conversion efficiency in fluorescent layer 350.

In contrast, since a proportion of void 60 in the region including at least part of second face 352 of fluorescent layer 350 (i.e., second region 350b) can be increased, it is possible to mitigate stress of fluorescent layer 350. When light source 310 includes light-transmissive plate 70, since coating layer 66 is not formed on a side facing light-transmissive plate 70 in fluorescent layer 350 (a side facing second face 352), void 60 makes it possible to mitigate stress generated in an interface between light-transmissive plate 70 and fluorescent layer 350 having different coefficients of thermal expansion. Thus, it is possible to reduce the occurrence of the crack in fluorescent layer 350.

### [4-4. Variation]

The following describes a light source according to a variation of Embodiment 4. The light source according to the variation has the same configuration as above-described light source 310, except for a region in which coating layer 66 is formed in a fluorescent layer. Hereinafter, the light source according to the variation will be described with reference to the drawings, with a focus on the differences from above-described light source 310.

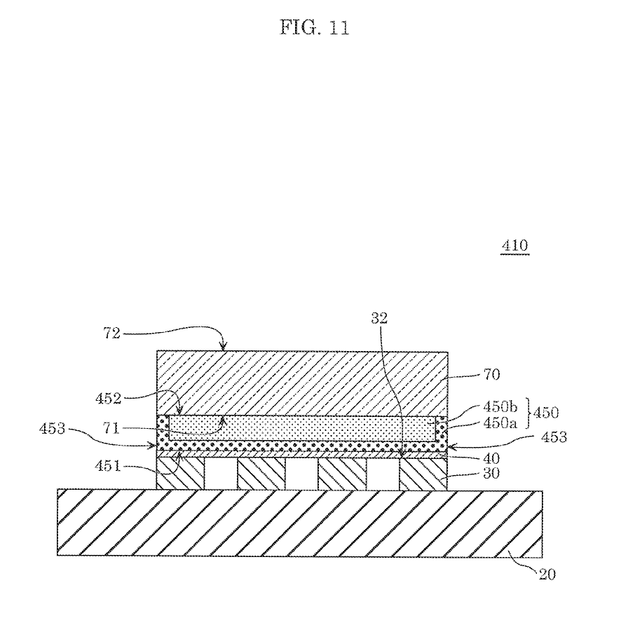

FIG. 11 is a schematic cross-sectional diagram illustrating a schematic configuration of light source 410 according to the variation. FIG. 11 shows a cross-section similar to the cross-section of light source 10 shown in FIG. 2. As shown in FIG. 11, light source 410 according to the variation includes substrate 20, solid-state light emitters 30, light-transmissive adhesive 40, fluorescent layer 450, and light-transmissive plate 70.

Fluorescent layer 450 has first face 451 facing light-emitting face 32 of solid-state light emitters 30, and second face 452 on a backside of first face 451. Moreover, as with above-described light source 310, in fluorescent layer 450, coating layer 66 is disposed in a region including first face 451, but is not disposed in a region including at least part of second face 452. To put it differently, fluorescent layer 450 includes first region 450a that is disposed on a side facing first face 451 and includes coating layer 66, and second region 450b that is disposed on a side facing second face 452 and does not include coating layer 66. Consequently, light source 410 according to the variation produces the same advantageous effects as above-described light source 310.

Furthermore, in the variation, coating layer 66 is disposed in a region including first face 451 and lateral face 453 of fluorescent layer 450 that connects first face 451 and second face 452. It is possible to further increase the strength of fluorescent layer 450 by disposing coating layer 66 in the region including lateral face 453 of fluorescent layer 450.

### Embodiment 5

The following describes a light source according to Embodiment 5. The light source according to Embodiment 5 has the same configuration as light source 110 according to Embodiment 2, except that the light source according to Embodiment 5 includes a reflector. Hereinafter, the light source according to Embodiment 5 will be described with reference to the drawings, with a focus on the differences from light source 110 according to Embodiment 2.

### [5-1. Schematic Configuration]

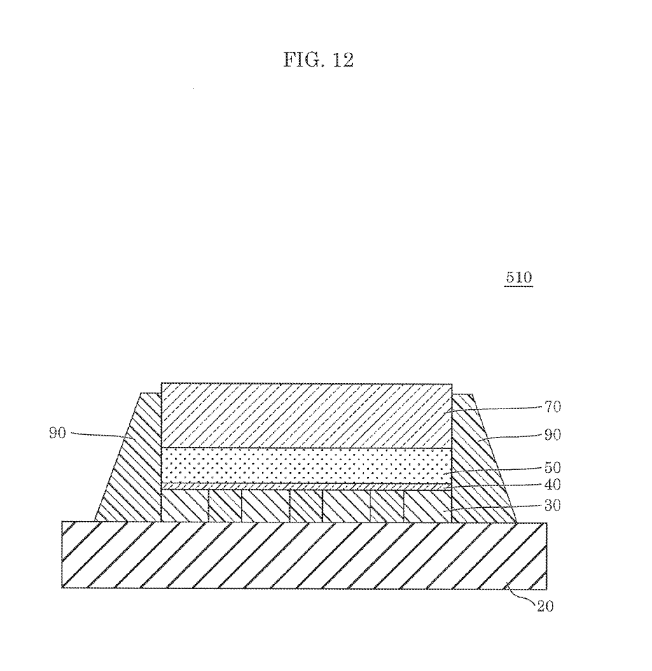

FIG. 12 is a schematic cross-sectional diagram illustrating a schematic configuration of light source 510 according to Embodiment 5. FIG. 12 shows a cross-section similar to the cross-section of light source 10 shown in FIG. 2. As shown in FIG. 12, as with light source 110 according to Embodiment 2, light source 510 according to Embodiment 5 includes substrate 20, solid-state light emitter 30, light-transmissive adhesive 40, fluorescent layer 50, and light-transmissive plate 70. Light source 510 according to Embodiment 5 further includes reflector 90.

Substrate 20, solid-state light emitter 30, light-transmissive adhesive 40, fluorescent layer 50, and light-transmissive plate 70 according to Embodiment 5 are the same in configuration as substrate 20, solid-state light emitter 30, light-transmissive adhesive 40, fluorescent layer 50, and light-transmissive plate 70 according to Embodiment 2.

### [5-2. Reflector]

Reflector 90 is a component that covers at least one of lateral faces of solid-state light emitter 30 and fluorescent layer 50 and reflects light emitted from at least one of solid-state light emitter 30 and fluorescent layer 50. In Embodiment 5, reflector 90 covers both the lateral faces of solid-state light emitter 30 and fluorescent layer 50.

Light exiting from each lateral face of solid-state light emitter 30 and fluorescent layer 50 is not used as emission light from light source 510, and may become a loss component. In Embodiment 5, however, reflector 90 is capable of reflecting light exiting from each lateral face of solid-state light emitter 30 and fluorescent layer 50, to solid-state light emitter 30 or fluorescent layer 50. As a result, it is possible to increase efficiency of light source 510.

Reflector 90 may be disposed between fluorescent layer 50 and solid-state light emitter 30, and substrate 20. In consequence, it is possible to further increase the efficiency of light source 510.

Reflector 90 may be any component that reflects visible light, and may be a titanium oxide-containing silicone resin.

### [5-3. Summary]

As described above, light source 510 according to Embodiment 5 may further include reflector 90 that covers a lateral face of at least one of solid-state light emitter 30 and fluorescent layer 50, and reflects light emitted from at least one of solid-state light emitter 30 and fluorescent layer 50, the lateral face being orthogonal to first face 51.

Reflector 90 is capable of reflecting light exiting from each lateral face of solid-state light emitter 30 and fluorescent layer 50, to solid-state light emitter 30 or fluorescent layer 50. As a result, it is possible to increase efficiency of light source 510.

### (Variations Etc.)

Although the light source of the present disclosure has been described based on the embodiments and variations, the present disclosure is not limited to the aforementioned embodiments and variations.

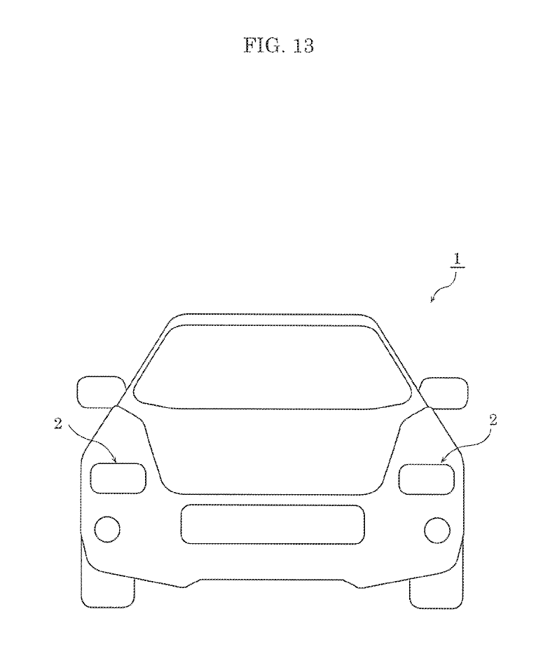

For example, it is possible to achieve one aspect of the present disclosure as an illumination device. It is also possible to achieve another aspect of the present disclosure as vehicle headlamps as shown in FIG. 13, which are one example of the illumination device. FIG. 13 is an external view of a vehicle including vehicle headlamps 2 according to a variation. Vehicle headlamps 2 shown in FIG. 13 each include the Light source according to any one of the aforementioned embodiments and variations. As a result, vehicle headlamps 2 produce the same advantageous effects as the aforementioned embodiments and variations. It should be noted that the light source according to any one of the aforementioned embodiments and variations is applicable to a light projector, an illumination device installed to a high ceiling, etc. other than vehicle headlamps 2.

Moreover, solid-state light emitter 30 may be a solid-state light emitter other than an LED. For example, solid-state light emitter 30 may be an organic electroluminescent (EL) element.

Furthermore, although the aforementioned embodiments and variations each have described the example in which the fluorescent materials of two types are included in the fluorescent layer, fluorescent materials of three or more types may be included in the fluorescent layer.

Moreover, the light sources according to Embodiment 3 and Embodiment 4 each need not include light-transmissive plate 70.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

For example, reflector 90 according to Embodiment 5 is applicable to the light sources according to Embodiment 1, Embodiment 3, and Embodiment 4.

What is claimed is:

1. A light source that emits white light,
wherein the white light has a correlated color temperature of at least 2700 K and at most 7200 K, a chromaticity deviation within ±10, and an average color rendering index of at least 80,
the light source comprising:
a solid-state light emitter that emits light having a first wavelength via a light-emitting face;
a fluorescent layer that
has a first face facing the solid-state light emitter and a second face positioned across from the first face,
receives, via the first face, the light emitted by the solid-state light emitter, and
transmits, via the second face, light having a second wavelength different from the first wavelength, the fluorescent layer being excited by the light received from the solid-state light emitter; and
a light-transmissive adhesive that bonds the light-emitting face of the solid-state light emitter and the first face of the fluorescent layer, the fluorescent layer includes:
a first fluorescent material of a first type having a first emission peak wavelength, and
a second fluorescent material of a second type having a second emission peak wavelength;
a binder that includes a light-transmissive inorganic compound that fixes the first fluorescent material and the second fluorescent material; and
a void that is provided between the first fluorescent material and the second fluorescent material.

2. The light source according to claim 1, further comprising:
a light-transmissive plate that is disposed on the second face of the fluorescent layer.

3. The light source according to claim 1,
wherein the first fluorescent material includes first particles having a diameter larger than or equal to a first diameter, and the second fluorescent material includes second particles having a diameter smaller than the first diameter.

4. The light source according to claim 1,
wherein the fluorescent layer further includes a light-transmissive coating layer that covers the binder and is made of a material different from a material of the binder.

5. The light source according to claim 1,
wherein the fluorescent layer further includes a light-transmissive coating layer that covers the binder and is made of a material different from a material of the binder, and
the light-transmissive coating layer is disposed in a region including the first face, and is not disposed in a region including at least part of the second face.

6. The light source according to claim 5,
wherein a proportion of the light-transmissive coating layer in the fluorescent layer is higher with decreasing distance to the solid-state light emitter.

7. The light source according to claim 5,
wherein the light-transmissive coating layer is disposed in a region including the first face and a lateral face of the fluorescent layer connecting the first face and the second face.

8. The light source according to claim 4,
wherein a difference in refractive index between the light-transmissive coating layer and the binder is at most 0.15.

9. The light source according to claim 1,
wherein the void has a volume proportion of at least 3% and at most 50% in the fluorescent layer.

10. The light source according to claim 1,
wherein the fluorescent layer has a thickness of at least 20 μm and at most 80 μm.

11. The light source according to claim 2,
wherein an exit face of the light-transmissive plate has an arithmetic average surface roughness of at least 50 nm, the exit face being positioned across from an entrance face of the light-transmissive plate facing the fluorescent layer.

12. The light source according to claim 2, further comprising:
an antireflection film that is disposed on an exit face of the light-transmissive plate, the exit face being positioned across from an entrance face of the light-transmissive plate facing the fluorescent layer.

13. The light source according to claim 2,
wherein a difference in refractive index between the light-transmissive plate and the binder is at most 0.2.

14. The light source according to claim 3,
wherein the first particles have a median diameter of at least 15 μm and at most 40 μm, and
the second particles have a median diameter of at least 5 μm and less than 15 μm.

15. The light source according to claim 3,
wherein a ratio of a median diameter of the first particles to a median diameter of the second particles is at least 1.5 and at most 2.5.

16. The light source according to claim 1, further comprising:
a plurality of solid-state light emitters, each of the plurality of solid-state light emitters being the solid-state light emitter,
a plurality of fluorescent layer blocks, each of the plurality of fluorescent layer blocks being spaced from one another and having a structure of the fluorescent layer,
wherein each of the fluorescent layer blocks is disposed above a different one of the plurality of solid-state light emitters.

17. The light source according to claim 1, further comprising:
a plurality of solid-state light emitters, each of the plurality of solid-state light emitters being the solid-state light emitter,
wherein the fluorescent layer is disposed above the plurality of solid-state light emitters.

18. The light source according to claim 1, further comprising:
a reflector that covers a lateral face of at least one of the solid-state light emitter and the fluorescent layer, and reflects light emitted from at least one of the solid-state light emitter and the fluorescent layer, the lateral face being orthogonal to the first face.

19. An illumination device, comprising:
a light source that emits white light,
wherein the white light has a correlated color temperature of at least 2700 K and at most 7200 K, a chromaticity deviation within ±10, and an average color rendering index of at least 80,
the light source comprising:
a solid-state light emitter that emits light having a first wavelength via a light-emitting face;
a fluorescent layer that
has a first face facing the solid-state light emitter and a second face positioned across from the first face,
receives, via the first face, the light emitted by the solid-state light emitter, and
transmits, via the second face, light having a second wavelength different from the first wavelength, the fluorescent layer being excited by the light received from the solid-state light emitter; and
a light-transmissive adhesive that bonds the light-emitting face of the solid-state light emitter and the first face of the fluorescent layer, the fluorescent layer includes:
a first fluorescent material of a first type having a first emission peak wavelength, and
a second fluorescent material of a second type having a second emission peak wavelength;
a binder that includes a light-transmissive inorganic compound that fixes the first fluorescent material and the second fluorescent material; and
a void that is provided between the first fluorescent material and the second fluorescent material.
